(19) United States
(12) Patent Application Publication
(10) Pub. No.: US 2026/0026279 A1
(43) Pub. Date: Jan. 22, 2026

(54) PROCESSING METHOD, METHOD OF MANUFACTURING SEMICONDUCTOR DEVICE, PROCESSING APPARATUS, AND RECORDING MEDIUM

(71) Applicant: Kokusai Electric Corporation, Tokyo (JP)

(72) Inventors: Takayuki YAMAMOTO, Toyama-shi (JP); Kaigo TAHARA, Toyama-shi (JP); Hideki HORITA, Toyama-shi (JP)

(73) Assignee: Kokusai Electric Corporation, Tokyo (JP)

(21) Appl. No.: 19/266,677

(22) Filed: Jul. 11, 2025

(30) Foreign Application Priority Data
Jul. 17, 2024 (JP) 2024-114204

(51) Int. Cl. H01L 21/311; H01L 21/02

(52) U.S. Cl. CPC H01L 21/31116; H01L 21/02532

(57) ABSTRACT

A technique includes: (a) providing a state where a product substrate and a nitrogen-containing object are disposed in a process container; and (b) etching a surface of the product substrate by using a substance X produced by supplying a fluorine-containing substance into the process container in which the product substrate and the nitrogen-containing object are disposed and causing the nitrogen-containing object to chemically react with the fluorine-containing substance.

### CROSS-REFERENCE TO RELATED APPLICATION

This application is based upon and claims the benefit of priority from Japanese Patent Application No. 2024-114204, filed on Jul. 17, 2024, the entire contents of which are incorporated herein by reference.

### TECHNICAL FIELD

The present disclosure relates to a processing method, a method of manufacturing a semiconductor device, a processing apparatus, and a recording medium.

### BACKGROUND

In the related art, as a process of manufacturing a semiconductor device, a process of etching a surface of a substrate may be performed.

### SUMMARY

Some embodiments of the present disclosure provide a technique capable of efficiently etching a surface of a substrate and increasing productivity.

According to embodiments of the present disclosure, there is provided a technique that includes (a) providing a state where a product substrate and a nitrogen-containing object are disposed in a process container; and (b) etching a surface of the product substrate by using a substance X produced by supplying a fluorine-containing substance into the process container in which the product substrate and the nitrogen-containing object are disposed and causing the nitrogen-containing object to chemically react with the fluorine-containing substance

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a processing apparatus suitably used in a first embodiment of the present disclosure, in which a portion of the process furnace is illustrated in a vertical cross-sectional view.

FIG. 2 is a schematic configuration diagram of the vertical process furnace of the processing apparatus suitably used in the first embodiment of the present disclosure, in which a portion of the process furnace is illustrated in a cross-sectional view taken along line A-A of FIG. 1.

FIG. 3 is a schematic configuration diagram of a controller of the processing apparatus suitably used in the first embodiment of the present disclosure, in which a control system of the controller is illustrated in a block diagram.

FIG. 4 is a diagram showing a process flow in the first embodiment of the present disclosure.

FIG. 5 is a diagram showing a process flow in a second embodiment of the present disclosure.

FIG. 6A is a schematic diagram showing a state inside a process container after performing step A in the first embodiment of the present disclosure, and FIG. 6B is a schematic diagram showing a state inside the process container after performing step A in the second embodiment of the present disclosure.

FIG. 7 is a schematic cross-sectional view showing a surface portion of a substrate after a film is formed by performing a cycle including steps A to D multiple times.

FIG. 8 is a diagram showing measurement results of an etching amount of a native oxide film on a substrate surface.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### First Embodiment of the Present Disclosure

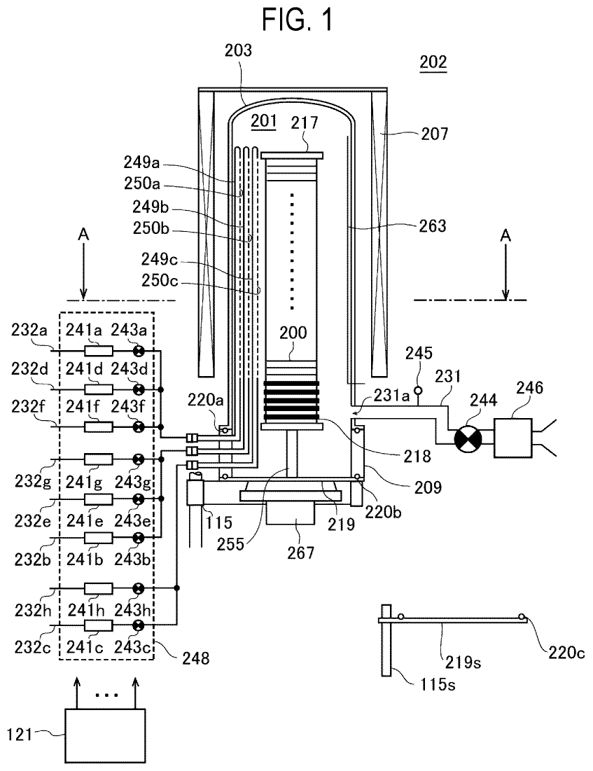

A first embodiment of the present disclosure is described below mainly with reference to FIGS. 1 to 3, 4 and 6A. Drawings used in the following description are schematic, and the dimensional relationships of respective elements, the proportions of respective elements, and the like shown in the drawings may not match the actual ones. Further, the dimensional relationships of respective elements, the proportions of respective elements, and the like may not match among multiple drawings.

### (1) Configuration of Processing Apparatus

As shown in FIG. 1, a process furnace 202 of a processing apparatus includes a heater 207 as a temperature regulator (heating part). The heater 207 is cylindrical and is installed vertically by being supported on a holding plate. The heater 207 also functions as an activator (exciter) that thermally activates (excites) a gas.

Inside the heater 207, a reaction tube 203 is disposed concentrically with the heater 207. The reaction tube 203 is made of a heat-resistant material such as, for example, quartz (SiO₂) or silicon carbide (SiC) and is formed in a cylindrical shape with an upper end thereof closed and a lower end thereof opened. Below the reaction tube 203, a manifold 209 is disposed concentrically with the reaction tube 203. The manifold 209 is made of a metallic material such as stainless steel (SUS) or the like and is formed in a cylindrical shape with open upper and lower ends. The upper end of the manifold 209 is engaged with the lower end of the reaction tube 203 and is configured to support the reaction tube 203. An O-ring 220a as a seal is provided between the manifold 209 and the reaction tube 203. The reaction tube 203 is installed vertically similar to the heater 207. A process container (reaction container) mainly includes the reaction tube 203 and the manifold 209. A process chamber 201 is formed in a cylindrical hollow portion of the process container. The process chamber 201 is configured to be capable of accommodating wafers 200 as product substrates. The wafers 200 are processed inside the process chamber 201.

Nozzles 249a to 249c as first to third suppliers are provided in the process chamber 201 so as to penetrate a side wall of the manifold 209. The nozzles 249a to 249c are also referred to as first to third nozzles, respectively. The nozzles 249a to 249c are made of, for example, a heat-resistant material such as quartz or SiC. Gas supply pipes 232a to 232c are connected to the nozzles 249a to 249c, respectively. The nozzles 249a to 249c are different nozzles, and the nozzles 249a and 249c are provided adjacent to the nozzle 249b.

On the gas supply pipes 232a to 232c, mass flow controllers (MFCs) 241a to 241c, which are flow rate controllers (flow rate control parts), and valves 243a to 243c, which are on-off valves, are respectively provided sequentially from an upstream of a gas flow. Gas supply pipes 232d and 232f are connected to the gas supply pipe 232a on a downstream of the valve 243a. Gas supply pipes 232e and 232g are connected to the gas supply pipe 232b on a downstream of the valve 243b. A gas supply pipe 232h is connected to the gas supply pipe 232c on a downstream of the valve 243c. On the gas supply pipes 232d to 232h, MFCs 241d to 241h and valves 243d to 243h are respectively provided sequentially from the upstream of the gas flow. The gas supply pipes 232a to 232h are made of a metallic material such as SUS or the like.

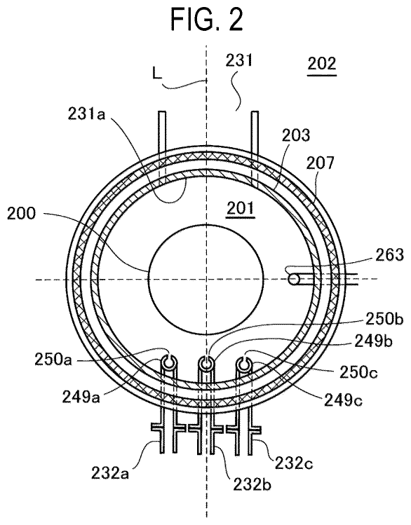

As shown in FIG. 2, each of the nozzles 249a to 249c is installed in a space with an annular shape in a plane view between an inner wall of the reaction tube 203 and the wafers 200 so as to extend upward in an arrangement direction of the wafers 200 from a lower portion to an upper portion of the inner wall of the reaction tube 203. In other words, the nozzles 249a to 249c are respectively installed in a region horizontally surrounding a wafer arrangement region in which the wafers 200 are arranged, on a lateral side of the wafer arrangement region so as to be aligned along the wafer arrangement region. In a plane view, the nozzle 249b is disposed to face a below-described exhaust port 231a on a straight line across centers of the wafers 200 in the process chamber 201. The nozzles 249a and 249c are disposed to sandwich a straight line L passing through centers of the nozzle 249b and the exhaust port 231a from both sides along the inner wall of the reaction tube 203 (an outer periphery of the wafer 200). The straight line Lis also a straight line passing through the centers of the nozzle 249b and the wafers 200. In other words, it may be said that the nozzle 249c is provided on an opposite side of the nozzle 249a with respect to the straight line L. The nozzles 249a and 249c are disposed in line symmetry with the straight line L as an axis of symmetry. Gas supply holes 250a to 250c for supplying gases are respectively formed on side surfaces of the nozzles 249a to 249c. The gas supply holes 250a to 250c are opened to face the exhaust port 231a in a plane view, and are capable of supplying gases toward the wafers 200. The gas supply holes 250a to 250c are provided in plurality from a lower portion to an upper portion of the reaction tube 203.

A fluorine (F)-containing substance is supplied from the gas supply pipe 232a into the process chamber 201 via the MFC 241a, the valve 243a, and the nozzle 249a.

A precursor is supplied from the gas supply pipe 232b into the process chamber 201 through the MFC 241b, the valve 243b, and the nozzle 249b. The precursor is used as one of film-forming agents.

A dopant agent is supplied from the gas supply pipe 232c into the process chamber 201 through the MFC 241c, the valve 243c, and the nozzle 249c. The dopant agent is used as one of the film-forming agents.

A reducing agent is supplied from the gas supply pipe 232d into the process chamber 201 via the MFC 241d, the valve 243d, the gas supply pipe 232a, and the nozzle 249a.

A reactant is supplied from the gas supply pipe 232e into the process chamber 201 through the MFC 241e, the valve 243e, the gas supply pipe 232b, and the nozzle 249b. The reactant is used as one of the film-forming agents.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c respectively. The inert gas acts as a purge gas, a carrier gas, a dilution gas, etc.

A fluorine-containing substance supply system mainly includes the gas supply pipe 232a, the MFC 241a, and the valve 243a. A precursor supply system mainly includes the gas supply pipe 232b, the MFC 241b, and the valve 243b. A dopant agent supply system mainly includes the gas supply pipe 232c, the MFC 241c, and the valve 243c. A reducing agent supply system mainly includes the gas supply pipe 232d, the MFC 241d, and the valve 243d. A reactant supply system mainly includes the gas supply pipe 232e, the MFC 241e, and the valve 243e. An inert gas supply system mainly includes the gas supply pipes 232f to 232h, the MFCs 241f to 241h, and the valves 243f to 243h. Each, some or an entirety of the precursor supply system, the dopant agent supply system, and the reactant supply system is also referred to as a film-forming agent supply system. Each, some or an entirety of the precursor supply system and the reactant supply system is also referred to as a coating agent (pre-coat agent) supply system.

Any or an entirety of the various supply systems described above may be configured as an integrated supply system 248 in which the valves 243a to 243h and the MFCs 241a to 241h are integrated. The integrated supply system 248 is connected to each of the gas supply pipes 232a to 232h, and is configured such that operations of supplying various substances (various gases) into the gas supply pipes 232a to 232h, i.e., opening/closing operations of the valves 243a to 243h and flow rate regulation operations by the MFCs 241a to 241h, are controlled by a controller 121 described later. The integrated supply system 248 is configured as an integrated or separate integrated unit, and may be attached and detached to and from the gas supply pipes 232a to 232h, etc. Therefore, maintenance, replacement, expansion, and the like of the integrated supply system 248 is configured to be capable of being performed on an integrated unit basis.

An exhaust port 231a for exhausting an atmosphere in the process chamber 201 is provided at a lower portion of a side wall of the reaction tube 203. As shown in FIG. 2, the exhaust port 231a is provided at a position facing the nozzles 249a to 249c (gas supply holes 250a to 250c) with the wafers 200 interposed therebetween in a plane view. The exhaust port 231a may be installed to extend from the lower portion to an upper portion of the side wall of the reaction tube 203, i.e., along the wafer arrangement region. An exhaust pipe 231 is connected to the exhaust port 231a. A vacuum pump 246 as a vacuum exhauster is connected to the exhaust pipe 231 via a pressure sensor 245 as a pressure detector (pressure detection part) for detecting a pressure inside the process chamber 201 and an APC (Auto Pressure Controller) valve 244 as a pressure regulator (pressure regulation part). The APC valve 244 is configured to be capable of performing or stopping vacuum exhaust of an interior of the process chamber 201 by being opened and closed in a state in which the vacuum pump 246 is being operated. Further, the APC valve 244 is configured to be capable of regulating the pressure inside the process chamber 201 by adjusting a valve opening degree based on pressure information detected by the pressure sensor 245 in a state in which the vacuum pump 246 is being operated. An exhaust system mainly includes the exhaust pipe 231, the APC valve 244, and the pressure sensor 245. The vacuum pump 246 may be included in the exhaust system.

A seal cap 219 as a furnace opening lid capable of airtightly closing an opening at the lower end of the manifold 209 is installed below the manifold 209. The seal cap 219 is made of a metallic material such as SUS or the like, and is formed in a disk shape. On an upper surface of the seal cap 219, there is installed an O-ring 220b as a seal which abuts against the lower end of the manifold 209. Below the seal cap 219, a rotator 267 for rotating a boat 217 to be described later is installed. A rotating shaft 255 of the rotator 267 is connected to the boat 217 by penetrating through the seal cap 219. The rotator 267 is configured to rotate the wafers 200 by rotating the boat 217. The seal cap 219 is configured to be raised or lowered in a vertical direction by a boat elevator 115 as a lift installed outside the reaction tube 203. The boat elevator 115 is configured as a transfer device (transfer mechanism) that loads and unloads (transfers) the wafers 200 into and out of the process chamber 201 by raising and lowering the seal cap 219. The boat elevator 115 functions as a device (preparation device) for providing a state where the product substrates and a nitrogen-containing object are disposed in the process container. When the nitrogen-containing object is disposed in the process container by forming a nitride film (precoat film) in the process container as in a second embodiment described later, each component of a processing apparatus (such as a precoat agent supply system) used in a process for forming the nitride film and the boat elevator 115 for disposing the product substrates in the process container function as the preparation device.

Below the manifold 209, a shutter 219s is installed as a furnace opening lid capable of airtightly closing the opening at the lower end of the manifold 209 in a state in which the seal cap 219 is lowered and the boat 217 is unloaded from the process chamber 201. The shutter 219s is made of a metallic material such as SUS or the like, and is formed in a disk shape. An O-ring 220c as a seal that abuts against the lower end of the manifold 209 is installed on an upper surface of the shutter 219s. Opening/closing operations (an elevating operation, a rotating operation, and the like) of the shutter 219s are controlled by a shutter opening/closing mechanism 115s.

A boat 217 as a substrate support is configured to support a plurality of wafers 200, for example, 25 to 200 wafers 200 in a horizontal posture and in multiple stages while vertically arranging the wafers 200 with the centers thereof aligned with each other, i.e., so as to arrange the wafers 200 at intervals. The boat 217 is configured to be capable of supporting a predetermined number of (one or more) dummy wafers as non-product substrates with a nitride film formed on the surface thereof, which are the nitrogen-containing object, in multiple stages, similar to the wafers 200 as the product substrates. The boat 217 is also configured to be capable of supporting side dummy wafers and filling dummy wafers. The boat 217 is made of a heat-resistant material such as quartz or SiC. At a lower portion of the boat 217, heat insulating plates 218 made of a heat-resistant material such as quartz or SiC are supported in multiple stages.

Inside the reaction tube 203, a temperature sensor 263 as a temperature detector is installed. By regulating a state of supply of electric power to the heater 207 based on temperature information detected by the temperature sensor 263, a temperature inside the process chamber 201 becomes a desired temperature distribution. The temperature sensor 263 is installed along the inner wall of the reaction tube 203.

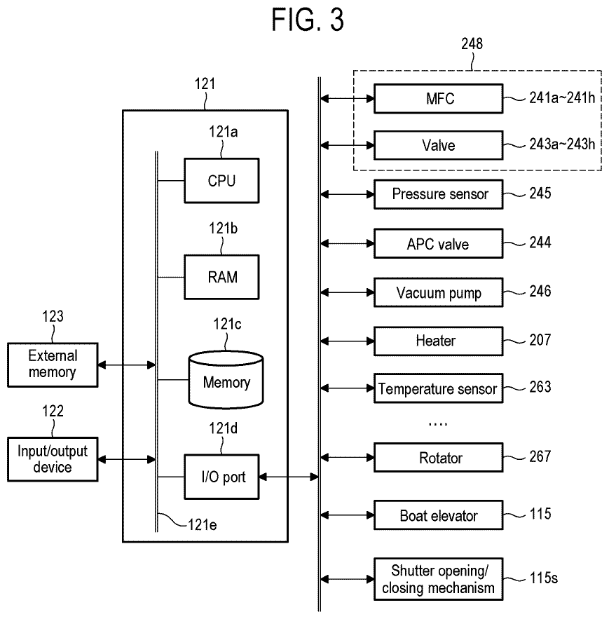

As shown in FIG. 3, the controller 121 as a control part (control means) is configured as a computer including a CPU (Central Processing Unit) 121a, a RAM (Random Access Memory) 121b, a memory 121c and an I/O port 121d. The RAM 121b, the memory 121c and the I/O port 121d are configured to be capable of exchanging data with the CPU 121a via an internal bus 121e. An input/output device 122 configured as, for example, a touch panel or the like is connected to the controller 121. In addition, an external memory 123 is configured to be capable of being connected to the controller 121. The processing apparatus may be configured to include one controller or a plurality of controllers. That is, control for performing a processing sequence described later may be performed using one controller or a plurality of controllers. The plurality of controllers may be configured as a control system in which the controllers are connected to each other via a wired or wireless communication network, and the control for performing the processing sequence described later may be performed by the entire control system. When the term “controller” is used in the present disclosure, it may include one controller, a plurality of controllers, or a control system configured by a plurality of controllers.

The memory 121c is composed of, for example, a flash memory, an HDD (Hard Disk Drive), an SSD (Solid State Drive), or the like. In the memory 121c, a control program for controlling the operation of the processing apparatus, a process recipe in which procedures and conditions of substrate processing to be described later are written, and the like are readably recorded and stored. The process recipe is a combination that executes, by the controller 121, each procedure of the below-described substrate processing in the processing apparatus so as to obtain a predetermined result. The process recipe functions as a program. Hereinafter, the process recipe, the control program and the like are also collectively and simply referred to as a program (program product). Further, the process recipe is also simply referred to as a recipe. When the term “program” is used herein, it may mean a case of including the recipe, a case of including the control program, or a case of including both the recipe and the control program. The RAM 121b is configured as a memory area (work area) in which programs, data and the like read by the CPU 121a are temporarily held.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opening/closing mechanism 115s, and the like.

The CPU 121a is configured to read and execute the control program from the memory 121c and to read the recipe from the memory 121c in response to an input of an operation command from the input/output device 122 or the like. The CPU 121a is configured to be capable of, according to contents of the recipe thus read, controlling the flow rate regulation operations for various substances (various gases) by the MFCs 241a to 241h, the opening/closing operations of the valves 243a to 243h, the pressure regulation operation by the APC valve 244 based on the opening/closing operation of the APC valve 244 and the pressure sensor 245, the start and stop of the vacuum pump 246, the temperature regulation operation of the heater 207 based on the temperature sensor 263, the rotation and the rotation speed adjustment operation of the boat 217 by the rotator 267, the raising and lowering operation of the boat 217 by the boat elevator 115, the opening/closing operation of the shutter 219s by the shutter opening/closing mechanism 115s, and the like.

The controller 121 may be configured by installing, on the computer, the above-described program recorded and stored in the external memory 123. The external memory 123 includes, for example, a magnetic disk such as an HDD or the like, an optical disk such as a CD or the like, a semiconductor memory such as a USB memory, an SSD, or the like, and so forth. The memory 121c and the external memory 123 are configured as a computer readable recording medium. Hereinafter, the memory 121c and the external memory 123 are collectively and simply referred to as a recording medium. As used herein, the term “recording medium” may refer to a case of including the memory 121c, a case of including the external memory 123, or a case of including both. Provision of the program to the computer may be performed by using communication means such as the Internet or a dedicated line without using the external memory 123.

### (2) Processing Process

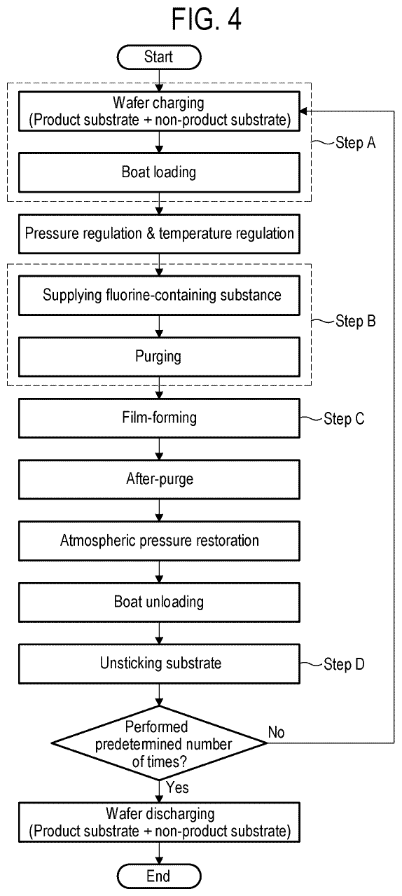

As a process (manufacturing method) of manufacturing a semiconductor device by using the above-described processing apparatus, a method (processing method) of processing a substrate, i.e., an example of a processing sequence that continuously performs, a predetermined number of times, a processing sequence for etching a surface of a wafer 200 as a product substrate and a processing sequence for growing a film on the wafer 200 after the etching, is mainly described with reference to FIG. 4. In the following description, the operation of each component constituting the processing apparatus is controlled by the controller 121. The processing apparatus is also referred to as a substrate processing apparatus, an etching processing apparatus, an etching apparatus, a film-forming processing apparatus, or a film-forming apparatus depending on the processing content. In addition, the processing method is also referred to as a substrate processing method, an etching processing method, an etching method, a film-forming processing method, or a film-forming method depending on the processing content.

In the processing sequence according to the present embodiment, there are performed:
(a) step A of providing a state where a wafer 200 as a product substrate and a nitrogen (N)-containing object are disposed in a process container; and
(b) step B of etching a surface of the wafer 200 by using a substance X produced by supplying a F-containing substance into the process container in which the wafer 200 and the N-containing object are disposed and causing the N-containing object to chemically react with the F-containing substance.

In the following example, there is described a case where the N-containing object to be disposed in the process container includes a dummy wafer serving as a non-product substrate with a nitride film formed on a surface of the non-product substrate.

Further, in the following example, there is described a case where after performing step B, the following is performed:
(c) step C of forming a film on the wafer 200 by supplying a film-forming agent into the process container in which the wafer 200 with an etched surface is disposed is further performed.

Further, in the following example, there is described a case where steps A to C are performed in a state in which the wafer 200 is supported by a boat 217 as a support,
(d) step D of unsticking the wafer 200, stuck to the boat 217 by the film formed in step C, by separating the wafer 200 from the boat 217 outside the process container is further performed, and
a cycle including steps A to D is performed multiple times.

The term “wafer” used herein may refer to a wafer itself or a stacked body of the wafer and a predetermined layer or film formed on a surface of the wafer. The phrase “a surface of a wafer” used herein may refer to the surface of the wafer itself or a surface of a predetermined film or the like formed on the wafer. The expression “a predetermined film is formed on a wafer” used herein may mean that the predetermined film is directly formed on a surface of the wafer itself or that the predetermined film is formed on a film or the like formed on the wafer. The term “substrate” used herein may be synonymous with the term “wafer.”

As used herein, the term “agent” or “substance” includes at least one selected from the group of gaseous substances and liquid substances. Liquid substances include mist-like substances. That is, each of the F-containing substance, the reducing agent, and the film-forming agents (the precursor, the dopant agent, the reactant, and the like) may include a gaseous substance, a liquid substance such as a mist-like substance, or both of them.

### (Step A)

First, a plurality of wafers 200 and dummy wafers with a nitride film formed on the surfaces of the dummy wafers are charged to the boat 217 (wafer charging).

An oxide may be formed on the surface of the wafer 200. The oxide may include at least one selected from the group of a silicon oxide film with a non-stoichiometric composition (SiOx film where x is a real number less than 2) and a silicon oxide film with a stoichiometric composition (SiO₂ film). The oxide may also include at least one selected from the group of a native oxide film and a chemical oxide film. The SiOx film and the SiO₂ film are also collectively referred to as SiO film below.

As the dummy wafer with a nitride film formed on its surface, a substrate with a surface on which a film containing a nitride such as silicon nitride (Si₃N₄, which is hereinafter also referred to as SiN), i.e., a nitride film such as a silicon nitride film (SiN film) is formed may be used. It is desirable that a predetermined number of dummy wafers are disposed for every wafer 200, i.e., every product substrate, or for every several product substrates. Hereinafter, the dummy wafer with a SiN film formed on its surface is also referred to as SiN wafer for the sake of convenience.

After the wafer charging is completed, the shutter 219s is moved by the shutter opening/closing mechanism 115s to open the opening at the lower end of the manifold 209 (shutter opening). Then, as shown in FIG. 1, the boat 217 supporting the wafers 200 and the SiN wafers is lifted by the boat elevator 115 and loaded into the process chamber 201 (boat loading). In this state, the seal cap 219 seals the lower end of the manifold 209 via the O-ring 220b.

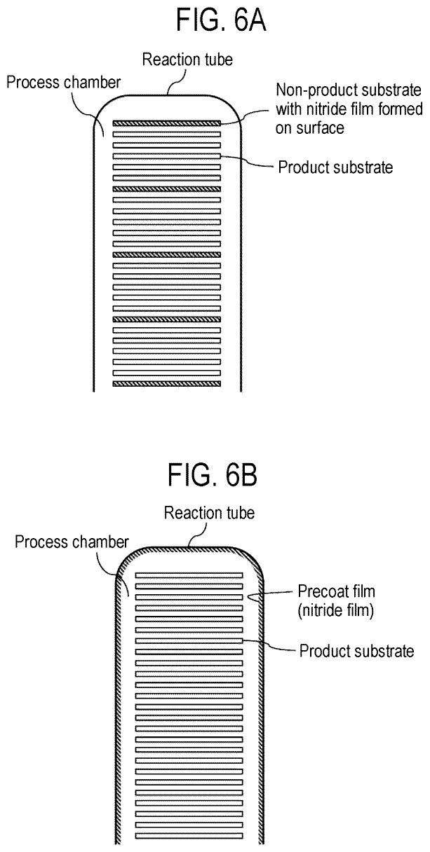

When the boat loading is completed, as shown in FIG. 6A, the wafers 200 as the product substrates and the non-product substrates (SiN wafers) with a nitride film formed on the surface thereof as the N-containing object are disposed in the process chamber 201. The SiN wafers as the non-product substrates are disposed at positions away from the wafers 200 as the product substrate and adjacent to the wafers 200.

### (Pressure Regulation and Temperature Regulation)

After the boat loading is completed, an inside of the process chamber 201, i.e., a space where the wafer 200 exists, is vacuum-exhausted (exhausted into a reduced pressure) by the vacuum pump 246 so that the pressure inside the process chamber 201 becomes a desired pressure (degree of vacuum). At this time, the pressure inside the process chamber 201 is measured by the pressure sensor 245, and the APC valve 244 is feedback-controlled based on the measured pressure information. In addition, the wafer 200 in the process chamber 201 is heated by the heater 207 so that the wafer 200 achieves a desired processing temperature. At this time, the state of supply of electric power to the heater 207 is feedback-controlled based on the temperature information detected by the temperature sensor 263 so that the inside of the process chamber 201 reaches a desired temperature distribution. Further, the rotation of the wafer 200 by the rotator 267 is started. The vacuum exhaust of the process chamber 201 and the heating and rotation of the wafer 200 are continuously performed at least until the processing on the wafer 200 is completed.

### (Step B)

Then, a F-containing substance is supplied into the process chamber 201 in which the wafers 200 as the product substrates and the SiN wafers as the N-containing object are disposed. Specifically, the valve 243a is opened to allow the F-containing substance to flow into the gas supply pipe 232a. A flow rate of the F-containing substance is regulated by the MFC 241a. The F-containing substance is supplied into the process chamber 201 via the nozzle 249a, and is exhausted from the exhaust port 231a. At this time, the F-containing substance is supplied to the wafer 200 and the N-containing object from a lateral side of the wafer 200 and the N-containing object, and the wafer 200 and the N-containing object are exposed to the F-containing substance (F-containing substance supply and exposure). At this time, the valves 243f to 243h may be opened to supply an inert gas into the process chamber 201 via each of the nozzles 249a to 249c.

By supplying the F-containing substance, under processing conditions to be described later, into the process chamber 201 in which the wafer 200 and the N-containing object are disposed, it becomes possible to chemically react the N-containing object with the F-containing substance to produce a substance X. The substance X includes a substance produced in a process of etching the N-containing object disposed in the process chamber 201 with the F-containing substance, e.g., a substance produced by decomposition of a reaction product generated in the process of etching the N-containing object with the F-containing substance. The substance X includes a substance containing nitrogen (N) and hydrogen (H). By producing the substance X in the process chamber 201 to which the F-containing substance is supplied, it becomes possible to etch the surface of the wafer 200, i.e., the oxide on the surface of the wafer 200, by using the substance X.

For example, when the oxide on the surface of the wafer 200 disposed in the process chamber 201 includes silicon oxide (SiO₂), the N-containing object disposed in the process chamber 201 includes silicon nitride (Si₃N₄), and the F-containing substance supplied into the process chamber 201 includes hydrogen fluoride (HF), it is possible to cause the reaction shown in the following formula to proceed under the conditions described below.

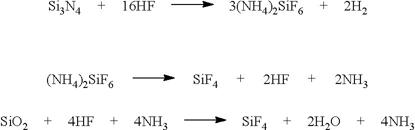

That is, in the process chamber 201, it is possible for the N-containing object (Si₃N₄) to chemically react with the F-containing substance (HF) to produce a reaction product in a solid state such as ammonium silicofluoride, i.e., ammonium hexafluorosilicate ((NH₄)₂SiF₆). Further, in the process chamber 201, it is possible for the solid reaction product to be decomposed (thermally decomposed) to produce hydrogen nitride such as ammonia (NH₃) as the substance X. By producing the substance X, containing N and H, such as NH₃ in the state where the F-containing substance (HF) exists, it is possible to promote an etching reaction of the oxide (SiO₂) present on the surface of the wafer 200 in the process chamber 201 to remove the oxide from the surface of the wafer 200. In addition, in the process of removing the oxide by the F-containing substance and the substance X, a reaction product in a solid state such as (NH₄)₂SiF₆ may be produced again, but in this reaction system, the solid reaction product is decomposed immediately after production thereof, and the above-mentioned reaction occurs as a chain reaction. That is, in this reaction system, the reaction, the production of the solid reaction product, the decomposition of the solid reaction product, and the etching occur repeatedly as a chain reaction, making it possible to prevent the solid reaction product from remaining as a solid on an outermost surface of the oxide to be etched.

According to the present disclosure, as described above, it is possible to start the etching reaction without being triggered by a reaction between the F-containing substance (HF) and water (H₂O). That is, according to the present disclosure, it is possible to start the etching reaction and etch the oxide on the surface of the wafer 200 without letting H₂O to exist in the process chamber 201 at the start of step B.

After etching the surface of the wafer 200, the valve 243a is closed to stop the supply of the F-containing substance into the process chamber 201. Then, the process chamber 201 is vacuum-exhausted to remove gaseous substances and the like remaining in the process chamber 201 from the inside of the process chamber 201. At this time, the valves 243f to 243h are opened to supply an inert gas into the process chamber 201 through the nozzles 249a to 249c. The inert gas supplied from the nozzles 249a to 249c acts as a purge gas, thereby purging the process chamber 201 (purging). A processing temperature when the purging is performed in this step is desirably the same as a processing temperature when the F-containing substance is supplied.

At this time, the valve 243d may be opened to supply a reducing agent into the process chamber 201 instead of or together with the inert gas. Also, at this time, cyclic purging may be performed using the inert gas and/or the reducing agent. When the cyclic purging is performed, the purging of the process chamber 201 by supplying at least one selected from the group of the inert gas and the reducing agent into the process chamber 201 and the exhausting (vacuum-exhausting) of the process chamber 201 may be performed alternately a predetermined number of times, desirably multiple times. In addition, in this case, in the state where the process chamber 201 is exhausted, the supply of the reducing agent into the process chamber 201 and the supply of the inert gas into the process chamber 201 may be performed alternately a predetermined number of times, desirably multiple times. Further, in this case, while one of the inert gas and the reducing agent is continuously supplied into the process chamber 201, the supply of the other of the inert gas and the reducing agent into the process chamber 201 and the exhausting of the process chamber 201 may be performed alternately a predetermined number of times, desirably multiple times. As a result, it is possible to efficiently and effectively discharge and remove substances remaining in the process chamber from the inside of the process chamber 201. When the inert gas is used as the purge gas, the process chamber 201 is purged mainly by a physical action. On the other hand, when the reducing agent is used as the purge gas, it is possible to generate a chemical action as well as the physical action, thus further improving the purging effect. When performing the cyclic purging, the opening and closing of the valves 243f to 243h and the valve 243d is appropriately controlled according to supply timings of the inert gas and the reducing agent.

Processing conditions when supplying the F-containing substance in step B are exemplified as follows.
Processing temperature: room temperature (25 degrees C.) to 200 degrees C., specifically 50 to 175 degrees C., more specifically 100 to 150 degrees C., even more specifically 120 to 150 degrees C.
Processing pressure: 10 to 3,000 Pa, specifically 10 to 2,000 Pa
Processing time: 1 to 120 minutes, specifically 1 to 100 minutes
F-containing substance supply flow rate: 0.5 to 3 slm, specifically 1 to 2 slm
Inert gas supply flow rate (per gas supply pipe): 0 to 10 slm, specifically 1 to 5 slm

In the present disclosure, when a numerical range such as “25 to 200 degrees C.” is indicated, it means that the lower limit and the upper limit are included in the range. Thus, for example, “25 to 200 degrees C.” means “25 degrees C. or higher and 200 degrees C. or lower”. The same applies to other numerical ranges. In the present disclosure, the processing temperature means the temperature of the wafer 200 or the temperature inside the process chamber 201, and the process pressure means the pressure inside the process chamber 201. When 0 slm is included in a supply flow rate, 0 slm means that the corresponding substance (gas) is not supplied. These also apply to the following descriptions.

Herein, if the processing temperature when supplying the F-containing substance in step B is set to less than room temperature (25 degrees C.), an etching rate may be increased. However, when other processing such as film-forming processing is performed at least either before or after the etching processing, a time needed to change the processing temperature between the etching processing and the other processing (temperature increasing time and/or temperature decreasing time) becomes too long, which may result in a decrease in productivity.

By setting the processing temperature to room temperature (25 degrees C.) or higher, it is possible to shorten the time needed to change the processing temperature between the etching processing and the other processing while maintaining a high etching rate, which makes it possible to suppress a decrease in the productivity. By setting the processing temperature to 50 degrees C. or higher, it is possible to further shorten the time needed to change the processing temperature between the etching processing and the other processing while maintaining a high etching rate, which makes it possible to further suppress a decrease in the productivity. By setting the processing temperature to 100 degrees C. or higher, it is possible to significantly shorten the time needed to change the processing temperature between the etching processing and the other processing while maintaining a high etching rate, which makes it possible to significantly improve the productivity. By setting the processing temperature to 120 degrees C. or higher, it is possible to further significantly shorten the time needed to change the processing temperature between the etching processing and the other processing while maintaining a high etching rate, which makes it possible to further significantly improve the productivity.

Further, if the above-mentioned processing temperature is set to a temperature higher than 200 degrees C., the time needed for changing the processing temperature between the etching processing and the other processing may be significantly shortened. However, the etching rate may become too low, resulting in a decrease in the productivity.

By setting the processing temperature to 200 degrees C. or less, it is possible to suppress a decrease in the etching rate while maintaining a significant reduction in the time needed for changing the processing temperature between the etching processing and the other processing, which makes it possible to suppress a decrease in the productivity. By setting the processing temperature to 175 degrees C. or less, it is possible to further suppress a decrease in the etching rate while maintaining a significant reduction in the time needed for changing the processing temperature between the etching processing and the other processing, which makes it possible to further suppress a decrease in the productivity. By setting the processing temperature to 150 degrees C. or less, it is possible to significantly suppress a decrease in the etching rate while maintaining a significant reduction in the time needed for changing the processing temperature between the etching processing and the other processing, which makes it possible to significantly suppress a decrease in the productivity.

In view of the above, the processing temperature is desirably set to a range from room temperature (25 degrees C.) to 200 degrees C., specifically from 50 degrees C. to 175 degrees C., more specifically from 100 degrees C. to 150 degrees C., and even more specifically from 120 degrees C. to 150 degrees C.

As the F-containing substance, for example, a substance containing hydrogen (H), such as hydrogen fluoride (HF), may be used. In addition, as the F-containing substance, for example, fluorine (F₂), nitrogen trifluoride (NF₃), chlorine trifluoride (ClF₃), chlorine fluoride (ClF), or the like may be used. As the F-containing substance, one or more of these substances may be used.

As the inert gas, a nitrogen (N₂) gas or a rare gas such as an argon (Ar) gas, a helium (He) gas, a neon (Ne) gas or a xenon (Xe) gas may be used. One or more of these gases may be used as the inert gas. This also applies to each step described later.

As the reducing agent, for example, a H-containing substance or a deuterium (D)-containing substance such as hydrogen (H₂) or deuterium (D₂) may be used. One or more of these substances may be used as the reducing agent.

After step B is completed, bake processing is performed in a reducing agent atmosphere as needed. Specifically, an output of the heater 207 is regulated so that the temperature of the wafer 200 is maintained at a processing temperature of the bake processing. Then, the valve 243d is opened to allow the reducing agent to flow into the gas supply pipe 232d. The reducing agent is supplied into the process chamber 201 through the gas supply pipe 232a and the nozzle 249a with the flow rate thereof regulated by the MFC 241d, and is exhausted from the exhaust port 231a. At this time, the reducing agent is supplied to the wafer 200 from the lateral side of the wafer 200, and the wafer 200 is exposed to the reducing agent.

Processing conditions in the bake processing are exemplified as follows.
Processing temperature: 700 to 1,000 degrees C., specifically 800 to 900 degrees C.
Processing pressure: 30 to 2,000 Pa, specifically 30 to 1,000 Pa
Processing time: 30 to 120 minutes, specifically 30 to 90 minutes
Reducing agent supply flow rate: 1 to 10 slm, specifically 1 to 5 slm
Inert gas supply flow rate (per gas supply pipe): 0 to 20 slm, specifically 1 to 10 slm

By supplying the reducing agent to the wafer 200 under the above-mentioned processing conditions, it becomes possible to remove substances including by-products such as organic matters and moisture remaining on the surface of the wafer 200 or in the process chamber 201 by allowing them to react with the reducing agent. At this time, if substances that could not be completely removed by the purging in step B remain on the surface of the wafer 200 or in the process chamber 201, it is also possible to remove these substances by allowing them to react with the reducing agent. That is, by this step, the surface of the wafer 200 and the inside of the process chamber 201 may be made clean, and the clean state may be maintained until step C is performed. If it is possible to keep the surface of the wafer 200 and the inside of the process chamber 201 clean after step B is performed and until step C is performed, the bake processing may be omitted. FIG. 4 shows an example in which the bake processing is omitted.

### (Step C)

After step B is completed or after the bake processing is completed, the output of the heater 207 is regulated so as to maintain the temperature of the wafer 200 at a predetermined processing temperature, which is described later. Then, a precursor as a film-forming agent and a reducing agent are supplied to the wafer 200.

Specifically, the valves 243b and 243d are opened to allow the precursor and the reducing agent to flow into the gas supply pipes 232b and 232d, respectively. Flow rates of the precursor and the reducing agent are regulated by the MFCs 241b and 241d, respectively. The precursor and the reducing agent are supplied into the process chamber 201 through the nozzles 249b and 249a, and are exhausted from the exhaust port 231a. At this time, the precursor and the reducing agent are supplied to the wafer 200 from the lateral side of the wafer 200, and the wafer 200 is exposed to the precursor and the reducing agent (precursor+reducing agent supply and exposure). At this time, the valves 243f to 243h may be opened to supply an inert gas into the process chamber 201 through the nozzles 249a to 249c, respectively.

By exposing the wafer 200 to the precursor and the reducing agent under processing conditions described below, it becomes possible to form a predetermined film on the surface of the wafer 200 from which the oxide is removed. When the surface of the wafer 200 is made of monocrystalline Si and when substances described below are used as the precursor and the reducing agent, it becomes possible to grow and form an epitaxial Si film as the film on the surface of the wafer 200. At this time, by the action of the reducing agent, it is possible to keep the surface of the wafer 200 and the inside of the process chamber 201 in a clean state, and allow epitaxial growth to occur appropriately, making it possible to form an epitaxial Si film with high purity.

After a predetermined film is formed on the surface of the wafer 200, the valves 243b and 243d are closed to stop the supply of the precursor and the reducing agent into the process chamber 201. Then, gaseous substances remaining in the process chamber 201 are removed from the inside of the process chamber 201 by the same processing procedure and processing conditions as those of the purging in step B (purging). A processing temperature in the purging in this step is desirably the same as the processing temperature when supplying the precursor and the reducing agent.

Processing conditions when supplying the precursor and the reducing agents in step C are exemplified as follows.
Processing temperature: 500 to 650 degrees C., specifically 550 to 600 degrees C.
Processing pressure: 4 to 200 Pa, specifically 1 to 120 Pa
Processing time: 10 to 120 min, specifically 20 to 60 min
Precursor supply flow rate: 0.1 to 5 slm, specifically 0.2 to 3 slm
Reducing agent supply flow rate: 1 to 20 slm, specifically 1 to 10 slm
Inert gas supply flow rate (per gas supply pipe): 0 to 20 slm, specifically 0.1 to 10 slm

As the precursor, for example, silicon hydrides such as monosilane (SiH₄), disilane (Si₂H₆), trisilane (Si₃H₈), and tetrasilane (Si₄H₁₀) may be used.

As the reducing agent, for example, H-containing substances or D-containing substances such as H₂ and D₂ may be used. As the reducing agent, one or more of these substances may be used.

### (After-Purge and Atmospheric Pressure Restoration)

After step C is completed, an inert gas as a purge gas is supplied into the process chamber 201 from each of the nozzles 249a to 249c and is exhausted through the exhaust port 231a. As a result, the inside of the process chamber 201 is purged, and gases, reaction by-products, and the like remaining in the process chamber 201 are removed from the inside of the process chamber 201 (after-purge). Thereafter, the atmosphere in the process chamber 201 is replaced with the inert gas (inert gas replacement), and the pressure in the process chamber 201 is returned to the atmospheric pressure (atmospheric pressure restoration).

### (Boat Unloading)

Thereafter, the seal cap 219 is lowered by the boat elevator 115, and the lower end of the manifold 209 is opened. Then, the processed wafers 200 are unloaded from the lower end of the manifold 209 to the outside of the reaction tube 203 while being supported by the boat 217 (boat unloading). After the boat is unloaded, the shutter 219s is moved and the opening at the lower end of the manifold 209 is sealed by the shutter 219s via the O-ring 220c (shutter closing).

### (Step D)

After the boat is unloaded, a process of unsticking the wafer 200 stuck to the boat 217 by the film formed in step C is performed outside the process chamber 201. This process may be performed, for example, by temporarily pulling (picking up) the wafer 200 apart from the boat 217. For example, this process may be performed by performing a reverse operation of the operation of charging the wafer 200 into the boat 217 in the wafer charging. At this time, if the SiN wafer sticks to the boat 217, the same process is performed on the SiN wafer as well. For example, the SiN wafer may be temporarily pulled apart from the boat 217 together with the wafer 200 to unstick the SiN wafer from the boat 217.

### [Performing a Predetermined Number of Times]

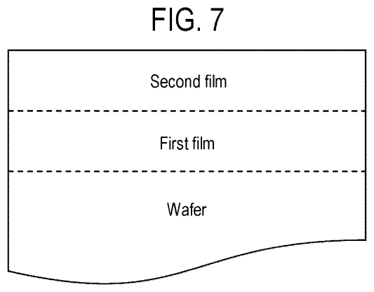

By performing a cycle including steps A to D a predetermined number of times (n times where n is an integer of 1 or 2 or more), it is possible to form a film of a desired thickness on the wafer 200. It is desirable to perform this cycle multiple times. That is, as illustrated in FIG. 7, it is desirable to set a thickness of a film (a thickness of each of a first film and a second film) formed by performing the cycle including steps A to D once to a thickness smaller than the desired film thickness, and to repeat the cycle multiple times until the thickness of the film stacked on the wafer 200 reaches a predetermined thickness. FIG. 7 shows an example in which the cycle is performed twice. Also, the first film in FIG. 7 indicates the film formed in a first cycle, the second film indicates the film formed in a second cycle, and the dashed lines indicate surface locations after the oxide is removed by etching in step B in each cycle. In addition, the dashed line between the wafer and the first film indicates the surface location after the oxide formed on the surface of the wafer is removed by etching in step B in the first cycle. Further, the dashed line between the first film and the second film indicates the surface location after the oxide formed on the surface of the first film as a result of unloading the wafer 200 from the process chamber 201 in step D of the first cycle is removed by etching in step B in the second cycle.

When the cycle is performed multiple times, during the wafer charging in the second and subsequent cycles, the wafers 200 and SiN wafers temporarily pulled apart from the boat 217 in step D are recharged to the boat 217. In addition, when the cycle is performed multiple times, if the surface of the non-product substrate (SiN wafer) serving as the N-containing object charged to the boat 217 after a certain cycle is covered with a film, it is desirable to start the next cycle after the non-product substrate is replaced with a new non-product substrate (SiN wafer) with an exposed nitride film on its surface. Further, when the cycle is performed multiple times, it is possible to continue to use the non-product substrate as the N-containing object as long as the nitride film is exposed on at least a portion of the surface of the non-product substrate.

### (Wafer Discharging)

After the film with the desired thickness is formed on the wafer 200, the processed wafers 200 and non-product substrates (SiN wafer) are discharged from the boat 217 (wafer discharging).

Thus, the processing process according to the embodiment of the present disclosure is completed.

The above-mentioned steps B and C are desirably performed in the same process chamber (in-situ). If a series of processing is performed in-situ, the wafer 200 is not exposed to the ambient air during the processing, and thus it is possible to perform consistent and stable processing while the wafer 200 is kept under vacuum.

### (3) Effects of the Present Embodiment

The present embodiment provides one or more of the following effects.

(a) In step A, a state of disposing the product substrate and the N-containing object in the process container is provided, and in step B, the F-containing substance is supplied into the process container. Thus, it is possible to etch the surface of the product substrate by using the substance X which is produced by causing the N-containing object to chemically react with the F-containing substance. By the action of the substance X, it is possible to promote the etching reaction and to perform the etching efficiently.

In step A, a state of disposing the product substrate and the N-containing object in the process container is provided, and in step B, the F-containing substance is supplied into the process container. This makes it possible to increase the processing temperature for the etching. When other processing such as film-forming processing is performed at least either before or after the etching processing, it is also possible to make the processing temperature for the etching close to the processing temperature for the other processing. This makes it possible to shorten the time needed to change the processing temperature between the etching processing and the other processing, i.e., at least either the temperature increasing time or the temperature decreasing time. Accordingly, it is possible to increase the productivity.

Further, by increasing the processing temperature for the etching, it is possible to decompose and remove the solid reaction products produced during the reaction in the state where the F-containing substance is supplied. This makes it possible to prevent the solid reaction products produced during the reaction from remaining on the outermost surface of the oxide to be etched, i.e., remaining in a solid state, and to prevent the reaction from not proceeding any further. This also makes it possible not to perform a separate process of raising the processing temperature and sublimating the solid reaction products after stopping the supply of the F-containing substance. Accordingly, it is possible to increase the productivity.

(b) In steps A and B, the N-containing object is disposed at a position away from and adjacent to the product substrate such that it is possible to optimize a location of production of the substance X to be at a location which is neither too close nor too far from the product substrate and which allows the etching reaction to occur effectively. This makes it possible to effectively obtain the above-mentioned actions.

(c) The above-mentioned actions may be effectively obtained when the N-containing object contains Si and the F-containing substance contains H. Further, the above-mentioned actions may be more effectively obtained when the N-containing object includes SiN and the F-containing substance includes HF.

(d) Since the substance X contains N and H, it is possible to effectively obtain the above-mentioned actions. Further, since the substance X is a substance produced in the process of etching the N-containing object with the F-containing substance, it is possible to more effectively obtain the above-mentioned actions. Further, since the substance X is a substance produced by decomposition of the reaction product produced in the process of etching the N-containing object with the F-containing substance, it is possible to more effectively obtain the above-mentioned actions.

(e) In step B, it is possible to effectively obtain the above-mentioned actions by etching the oxide on the surface of the product substrate. Also, it is possible to more effectively obtain the above-mentioned actions by the oxide including a silicon oxide film with a non-stoichiometric composition. In addition, it is possible to more effectively obtain the above-mentioned actions by the oxide including at least one selected from the group of a native oxide film and a chemical oxide film.

(f) By setting the processing temperature in step B to 100 degrees C. or higher, it is possible to significantly shorten the time needed to change the processing temperature between the etching processing and the other processing while maintaining a high etching rate, thereby significantly improving the productivity. In addition, by setting the processing temperature in step B to 100 degrees C. or higher, it is possible to effectively prevent the solid reaction product produced during the etching reaction from remaining on the outermost surface of the oxide to be etched, thereby preventing the reaction from not proceeding any further.

By setting the processing temperature in step B to 120 degrees C. or higher, it is possible to further significantly shorten the time needed to change the processing temperature between the etching processing and the other processing while maintaining a high etching rate, thereby further significantly improving the productivity. In addition, by setting the processing temperature in step B to 120 degrees C. or higher, it is possible to more effectively prevent the solid reaction product produced during the etching reaction from remaining on the outermost surface of the oxide to be etched, thereby preventing the reaction from not proceeding any further.

(g) In step B, a reaction between the F-containing substance and H₂O is not needed as a trigger for etching, and as such, it is not need to perform regulation at least at the start of step B to let a trace amount of H₂O be present in the process container. In addition, since it is not needed to let a trace amount of H₂O be present in the process container at the start of step B, it is possible to increase the processing temperature for the etching and to maintain the inside of the process container in a clean state.

(h) The N-containing object includes a non-product substrate with a nitride film formed on its surface, and in steps A and B, the non-product substrate is disposed for every product substrate or for every several product substrates in the process container, thereby making it possible to effectively obtain the above-mentioned actions. Further, the N-containing object (non-product substrate with a nitride film formed on its surface) is possible to be supported in the same manner as the product substrate by the support that supports the product substrate. As such, providing a separate member for disposing the N-containing object in the process container is not needed. In addition, it is possible to transfer the N-containing object (non-product substrate with a nitride film formed on its surface) to the support using the same transfer device just like the product substrate, and thus providing a separate transfer device for transferring the N-containing object is not needed.

(i) In step C, the film-forming agent is supplied into the process container in which the product substrate with an etched surface is disposed, and the film is formed on the product substrate. This makes it possible to reduce an impurity concentration (oxygen concentration, etc.) at an interface between the product substrate and the film.

(j) By performing the cycle including steps A to D multiple times, it is possible to reduce the impurity concentration (oxygen concentration, etc.) at the interface between the product substrate and the film, and also to reduce an impurity concentration (oxygen concentration, etc.) at an interface between the film formed in the first cycle and the film formed in the second cycle.

(k) In step B, since the N-containing object and the F-containing substance are chemically reacted in the process container to generate the substance X, there is no need to provide a separate supply line for supplying the substance X into the process container, and thus it is possible to reduce cost of the apparatus. In addition, it is possible to simplify the supply system inasmuch as the supply line for supplying the substance X is omitted. This makes it possible to reduce labor and cost needed for maintaining the supply system.

(1) The above-mentioned effects are still obtainable even when a predetermined substance is arbitrarily selected from the above-mentioned various F-containing substances, various film-forming agents, various reducing agents, and various inert gases.

### Second Embodiment of the Present Disclosure

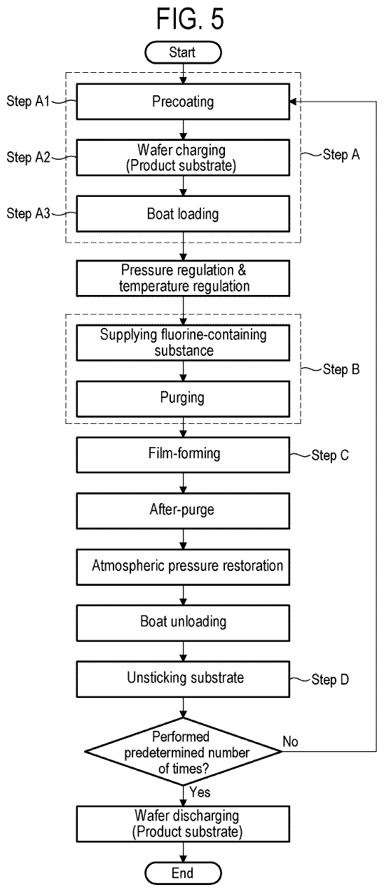

Next, the second embodiment of the present disclosure is described mainly with reference to FIGS. 5 and 6B.

In this embodiment, the N-containing object disposed in the process container in steps A and B includes a nitride film formed in the process container. In this respect, this embodiment differs from the above-described first embodiment. Hereinafter, a processing sequence including step A (steps A1, A2 and A3) and step B according to this embodiment is described.

First, in a state where no wafer 200 is accommodated in the process chamber 201, the pressure and temperature in the process chamber 201 are regulated as in the first embodiment described above, and then a process of forming a nitride film as a precoat film in the process chamber 201, i.e., precoating, is performed (step A1). In step A1, a step of supplying a precursor as a precoat agent into the process chamber 201 (precursor supply) and a step of supplying a reactant as a precoat agent into the process chamber 201 (reactant supply) are sequentially performed a predetermined number of times.

In supplying the precursor, the valve 243b is opened to allow the precursor to flow into the gas supply pipe 232b. A flow rate of the precursor is regulated by the MFC 241b. The precursor is supplied into the process chamber 201 via the nozzle 249b, and is exhausted from the exhaust port 231a. At this time, surfaces of members in the process chamber 201 are exposed to the precursor (precursor supply and exposure). At this time, the valves 243f to 243h may be opened to supply an inert gas into the process chamber 201 via each of the nozzles 249a to 249c.

After the precursor is supplied into the process chamber 201 for a predetermined time, the valve 243b is closed to stop the supply of the precursor into the process chamber 201. Then, gaseous substances and the like remaining in the process chamber 201 are removed from the inside of the process chamber 201 by the same processing procedure and processing conditions as those of the purging in step B of the first embodiment described above (purging).

In supplying the reactant, the valve 243e is opened to allow the reactant to flow into the gas supply pipe 232e. A flow rate of the reactant is regulated by the MFC 241e. The reactant is supplied into the process chamber 201 via the nozzle 249b, and is exhausted from the exhaust port 231a. At this time, the surfaces of the members in the process chamber 201 are exposed to the reactant (reactant supply and exposure). At this time, the valves 243f to 243h may be opened to supply an inert gas into the process chamber 201 via each of the nozzles 249a to 249c.

After the reactant is supplied into the process chamber 201 for a predetermined time, the valve 243e is closed to stop the supply of the reactant into the process chamber 201. Then, gaseous substances and the like remaining in the process chamber 201 are removed from the process chamber 201 by the same processing procedure and processing conditions as those of the purging in step B of the first embodiment described above (purging).

Then, by performing a cycle including the supply of the precursor and the supply of the reactant a predetermined number of times (n times where n is an integer of 1 or 2 or more), a nitride film (precoat film) with a desired thickness is formed on the surfaces of the members in the process chamber 201, e.g., on the inner wall of the reaction tube 203, etc. The precoating may be performed in a state in which an empty boat 217 is accommodated in the process chamber 201. In this case, a nitride film (precoat film) with a desired thickness is formed on the surfaces of the members in the process chamber 201, e.g., on the inner wall of the reaction tube 203 and the surface of the boat 217, etc. When substances described later are used as the precursor and the reactant, respectively, a silicon nitride film (SiN film) is formed as the nitride film on the surfaces of the members in the process chamber 201.

Processing conditions when supplying the precursor in step A1 are exemplified as follows.
Processing temperature: 300 to 800 degrees C., specifically 400 to 650 degrees C.
Processing pressure: 1 to 2,000 Pa, specifically 1 to 1,333 Pa
Processing time: 1 to 180 seconds, specifically 10 to 120 seconds
Precursor supply flow rate: 0.001 to 2 slm, specifically 0.01 to 1 slm
Inert gas supply flow rate (per gas supply pipe): 0 to 20 slm, specifically 0.1 to 10 slm

Processing conditions when supplying the reactant in step A1 are exemplified as follows.
Processing temperature: 300 to 800 degrees C., specifically 400 to 650 degrees C.
Processing pressure: 1 to 4,000 Pa, specifically 1 to 1,333 Pa
Processing time: 1 to 180 seconds, specifically 10 to 120 seconds
Reactant supply flow rate: 0.01 to 20 slm, specifically 0.01 to 10 slm
Inert gas supply flow rate (per gas supply pipe): 0 to 20 slm, specifically 0.1 to 10 slm

Examples of the precursor include chlorosilane such as monochlorosilane (SiH₃Cl), dichlorosilane (SiH₂Cl₂), trichlorosilane (SiHCl₃), tetrachlorosilane (SiCl₄), hexachlorodisilane (Si₂Cl₆) or the like, and the silicon hydride exemplified as the precursor in step C of the first embodiment. One or more of these substances may be used as the precursor.

Examples of the reactant include hydrogen nitride such as ammonia (NH₃), diazene (N₂H₂), hydrazine (N₂H₄), N₃H₈ or the like. One or more of these substances may be used as the reactant.

After the nitride film with a desired thickness is formed on the surfaces of the members inside the process chamber 201, after-purge and atmospheric pressure restoration are performed according to the same processing procedure as in the first embodiment described above.

Thereafter, a plurality of wafers 200 as product substrates are charged to the boat 217 by the same processing procedure as in the first embodiment described above (wafer charging) (step A2). Unlike the first embodiment, in this embodiment, non-product substrates (SiN wafers) with a nitride film formed on their surfaces are not charged to the boat 217. Therefore, in this embodiment, the number of product substrates that is processed at one time may be increased accordingly, which makes it possible to increase the productivity.

After the wafer charging is completed, the boat 217 supporting the wafers 200 is loaded into the process chamber 201 by the same processing procedure as in the first embodiment described above (boat loading), and the wafers 200 are disposed in the process chamber 201 in which the nitride film is formed (step A3). Upon completion of the boat loading, as shown in FIG. 6B, the wafers 200 as product substrates and the N-containing object (the nitride film formed on the surfaces of the members in the process chamber 201) are disposed in the process chamber 201. As in the first embodiment described above, the N-containing object is disposed at a position away from the wafers 200 and adjacent to the wafers 200.

Processing procedures and processing conditions in each step performed thereafter may be the same as the processing procedures and processing conditions in each step in the above-mentioned first embodiment. Also, in step B, it is possible to etch the surface of the product substrate by using a substance X which is produced by causing the nitride film formed on the surfaces of the members in the process chamber 201, e.g., on the inner wall of the reaction tube 203, to chemically react with the F-containing substance. As in the above-mentioned first embodiment, by the action of the substance X, it is possible to promote the etching reaction and to perform etching efficiently.

In this embodiment as well, it is possible to form a film with a desired thickness on the wafer 200 by performing a cycle including steps A to D a predetermined number of times (n times where n is an integer of 1, 2 or more). If the nitride film formed on the surfaces of the members in the process chamber 201 in step A1 is covered with a film after one cycle is completed, a nitride film (precoat) is needed to be formed on the surfaces of the members in the process chamber 201 again before performing the next cycle, and a cycle including steps A (A1, A2 and A3) to D is needed to be performed a predetermined number of times. FIG. 5 shows an example in which the precoating is performed for each cycle. However, if the nitride film formed on the surfaces of the members in the process chamber 201 is not entirely covered with a film after one cycle is completed, and if at least a portion of the nitride film is exposed, it is not needed to perform the precoating again. Then, a cycle including steps A (A2 and A3) to D may be performed a predetermined number of times. When performing the cycle multiple times, it is possible to continue to use the nitride film formed on the surfaces of the members in the process chamber 201 as the N-containing object as long as at least a portion of the nitride film is exposed.

In this embodiment, the same effects as in the first embodiment are obtained. In addition, according to this embodiment, it is possible to form the N-containing object on the surfaces of the members in the process container, and as such a separate member for disposing the N-containing object is not needed to be provided in the process container. In addition, according to this embodiment, it is not needed to use a non-product substrate with a nitride film formed on its surface. Therefore, it is possible to fully charge the support with the product substrates, making it possible to increase the number of product substrates processed at one time and improve the productivity. In addition, according to this embodiment, it is possible to conformally and uniformly form the N-containing object on the surfaces of the members in the process container, e.g., on the entire inner wall of the reaction tube 203, making it possible to produce the substance X uniformly throughout an entire area inside the process container and improve uniformity of the etching processing.

### Other Embodiments of the Present Disclosure

The embodiments of the present disclosure are specifically described above. However, the present disclosure is not limited to the above-described embodiments, and various changes may be made without departing from the spirit of the present disclosure.

For example, in step B of the first and second embodiments described above, the F-containing gas may be supplied intermittently, i.e., in a pulsed manner, into the process container. For example, the supply of the F-containing gas into the process container and the purging and/or vacuum exhaust of the process container may be alternately performed a predetermined number of times (m times where m is an integer of 1 or 2 or more). In this case, the same effects as those of the first and second embodiments described above are obtained. In addition, according to the embodiment, by intermittently removing reaction products and residual gases from the process container during the etching to reset the reaction, it is possible to suppress occurrence of an excessive etching reaction, and to improve controllability of an etching amount.

In addition, for example, in step C of the first and second embodiments described above, in addition to the precursor and the reducing agent, a dopant agent may be supplied to the product substrate as a film-forming agent. The dopant agent may be supplied from the dopant agent supply system described above. As the dopant agent, a substance containing any of Group 15 elements such as phosphorus (P) and arsenic (As) and Group 13 elements such as boron (B) may be used. As the dopant agent, for example, phosphine (PH₃), arsine (AsH₃), diborane (B₂H₆), trichloroborane (BCl₃), and the like may be used. As the dopant agent, one or more of these substances may be used. In this embodiment, the same effects as those of the first and second embodiments described above are obtained. In addition, according to this embodiment, it is possible to form a film doped with a dopant (P, As, B, etc.) on the product substrate.

In addition, for example, in step C of the first and second embodiments described above, a semiconductor element-containing film may be formed on the product substrate by using a substance containing a semiconductor element other than Si. For example, a substance containing germanium (Ge), such as monogermane (GeH4), may be used as the precursor to form a Ge-containing film on the product substrate. Further, for example, a Si-containing substance and a Ge-containing substance may be used as the precursor to form a Si- and Ge-containing film on the product substrate. Further, for example, a substance containing a metal element such as tungsten (W), molybdenum (Mo), aluminum (Al), titanium (Ti), zirconium (Zr), hafnium (Hf) or tantalum (Ta) may be used as the precursor to form a metal element-containing film on the product substrate. In these cases as well, the same effects as those of the first and second embodiments described above are obtained.

Further, for example, in step C of the first and second embodiments described above, a non-crystalline film (amorphous film), a polycrystalline film, or an amorphous/polycrystalline mixed film in addition to the epitaxial film may be formed on the product substrate. In these cases as well, the same effects as those of the first and second embodiments described above are obtained.

In addition, for example, in the precoating (step A1) in step A of the second embodiment described above, the precursor and the reactant may be simultaneously supplied into the process container. In this embodiment as well, the same effects as those of the first and second embodiments described above are obtained.

It is desirable that the recipe used for each processing is prepared separately according to the processing contents and are recorded and stored in the memory 121c via an electric communication line or the external memory 123. When starting each processing, it is desirable that the CPU 121a adequately selects an appropriate recipe from a plurality of recipes recorded and stored in the memory 121c according to the process contents. This allows various processing with good reproducibility for films of various film types, composition ratios, film qualities, and film thicknesses to be performed in the processing apparatus. This also reduces the burden on the operator and enables each processing to be started quickly while avoiding operational errors.

The above-mentioned recipe is not limited to newly created ones, but may be prepared, for example, by modifying an existing recipe that is already installed in the processing apparatus. When modifying a recipe, the modified recipe may be installed in the processing apparatus via an electric communication line or a recording medium on which the recipe is recorded. In addition, an existing recipe that is already installed in the processing apparatus may be directly modified by operating the input/output device 122 provided in the existing processing apparatus.

In the above-described embodiments, there are described the examples in which the processing is performed using a batch-type processing apparatus that processes multiple substrates at a time. The present disclosure is not limited to the above-described embodiments, and may be applied to, for example, a case where the processing is performed using a single-substrate-type processing apparatus that processes one or several substrates at a time. In addition, in the above-described embodiments, there are described the examples in which the processing is performed using the processing apparatus with a hot-wall-type process furnace. The present disclosure is not limited to the above-described embodiments, and may be applied to a case where the processing is performed using a processing apparatus with a cold-wall-type process furnace.

In the above-described embodiments, there is described the case where the above-mentioned processing sequence is performed in the same process chamber of the same processing apparatus (in-situ). The present disclosure is not limited to the above-described embodiments. For example, any one step of the above-mentioned processing sequence and any other step thereof may be performed in different process chambers of different processing apparatuses (ex-situ), or may be performed in different process chambers of the same processing apparatus.

Even when these processing apparatuses are used, each processing may be performed under the same processing procedures and processing conditions as those of the above-described embodiments and modifications. The same effects as those of the above-described embodiments and modifications are obtained.

The above-described embodiments and modifications may be used in combination as appropriate. The processing procedures and processing conditions at this time may be, for example, the same as the processing procedures and processing conditions of the above-described embodiments and modifications.

### Example

As an Example, a Si wafer with a native oxide film formed on its surface and a Si wafer with a SiN film formed on its surface (hereinafter referred to as SiN wafer) are disposed in the process container with no nitride film formed therein, and a HF gas is supplied into the process container to etch the surface of the Si wafer. At this time, an etching amount is measured for each case where the processing temperature during the supply of the HF gas is set to 30, 50, 100, 150, and 200 degrees C. Other processing conditions during the supply of the HF gas are set to predetermined conditions within the processing condition range used in step B of the above-described embodiments.

As a Comparative Example, without disposing a SiN wafer, a Si wafer with a native oxide film formed on its surface is disposed in the process container with no nitride film formed therein, and a HF gas is supplied into the process container to etch the surface of the Si wafer. At this time, an etching amount is measured for each case where the processing temperature during the supply of the HF gas is set to 30, 55, 75, and 100 degrees C. Other processing conditions during the supply of the HF gas are set to be the same as those in the Example.

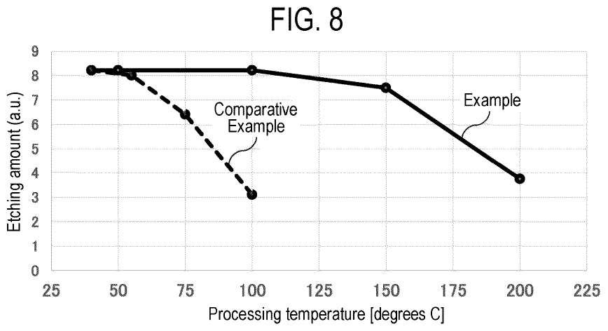

FIG. 8 shows measurement results of the etching amount of the native oxide film on the surface of the Si wafer. The horizontal axis in FIG. 8 indicates the processing temperature [degrees C.] when the HF gas is supplied, and the vertical axis indicates the etching amount [a.u.] of the native oxide film. The solid line in FIG. 8 indicates the measurement results of the etching amount of the native oxide film in the Example, and the dashed line indicates the measurement results of the etching amount of the native oxide film in the Comparative Example. As shown in FIG. 8, the etching amount of the native oxide film in the Example shows no decrease until the processing temperature reaches 100 degrees C., and an amount of decrease is small even in the range of 100 degrees C. to 150 degrees C. As shown in FIG. 8, a sufficiently practical etching amount is obtained even in the range of 150 degrees C. to 175 degrees C. In contrast, it may be seen that the etching amount of the native oxide film in the Comparative Example decreases significantly in the temperature range exceeding 55 degrees C. That is, according to the Example, it is possible to efficiently etch the native oxide film on the surface of the Si wafer at a relatively high temperature, and it is possible to significantly increase the productivity.

According to the present disclosure in some embodiments, it is possible to efficiently etch a surface of a substrate and increase productivity.

While certain embodiments are described, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method comprising:
(a) providing a state where a product substrate and a nitrogen-containing object are disposed in a process container; and
(b) etching a surface of the product substrate by using a substance X produced by supplying a fluorine-containing substance into the process container in which the product substrate and the nitrogen-containing object are disposed and causing the nitrogen-containing object to chemically react with the fluorine-containing substance.

2. The processing method of claim 1, wherein the nitrogen-containing object is disposed at a position away from the product substrate and adjacent to the product substrate.

3. The processing method of claim 1, wherein the nitrogen-containing object contains silicon, and the fluorine-containing substance contains hydrogen.

4. The processing method of claim 1, wherein the nitrogen-containing object includes silicon nitride, and the fluorine-containing substance includes hydrogen fluoride.

5. The processing method of claim 4, wherein the substance X contains nitrogen and hydrogen.

6. The processing method of claim 1, wherein the substance X is produced during an etching of the nitrogen-containing object by the fluorine-containing substance.

7. The processing method of claim 1, wherein the substance X is produced by decomposition of a reaction product produced during an etching of the nitrogen-containing object by the fluorine-containing substance.

8. The processing method of claim 1, wherein in (b), an oxide on the surface of the product substrate is etched.

9. The processing method of claim 8, wherein the oxide includes a silicon oxide film with a non-stoichiometric composition.

10. The processing method of claim 8, wherein the oxide includes at least one selected from the group of a native oxide film and a chemical oxide film.

11. The processing method of claim 1, wherein a processing temperature in (b) is 100 degrees C. or higher.

12. The processing method of claim 1, wherein a processing temperature in (b) is 120 degrees C. or higher.

13. The processing method of claim 1, wherein (b) is performed under conditions that cause the etching to start without triggering a reaction between the fluorine-containing substance and H₂O.

14. The processing method of claim 1, wherein the nitrogen-containing object includes a non-product substrate with a nitride film formed on a surface of the non-product substrate.

15. The processing method of claim 14, wherein in (a) and (b), the non-product substrate is disposed for every product substrate or for every several product substrates in the process container.

16. The processing method of claim 1, wherein the nitrogen-containing object includes a nitride film formed in the process container.

17. The processing method of claim 16, wherein (a) includes:
(a1) forming the nitride film in the process container; and
(a2) disposing the product substrate in the process container in which the nitride film is formed.

18. The processing method of claim 1, further comprising:
(c) forming a film on the product substrate by supplying a film-forming agent into the process container in which the product substrate with an etched surface is disposed.

19. The processing method of claim 18, wherein (a), (b) and (c) are performed while the product substrate is supported by a support, and
wherein the processing method further comprises:
(d) outside the process container, unsticking the product substrate stuck to the support by the film by separating the product substrate from the support,
wherein a cycle including (a), (b), (c) and (d) is performed multiple times.

20. A method of manufacturing a semiconductor device comprising the processing method of claim 1.

21. A processing apparatus, comprising:
a process container;
a device configured to provide a state where a product substrate and a nitrogen-containing object are disposed in the process container;
a fluorine-containing substance supply system configured to supply a fluorine-containing substance into the process container; and
a controller configured to be capable of controlling the device and the fluorine-containing substance supply system so as to perform (a) providing the state where the product substrate and the nitrogen-containing object are disposed in the process container, and (b) etching a surface of the product substrate by using a substance X produced by supplying the fluorine-containing substance into the process container in which the product substrate and the nitrogen-containing object are disposed and causing the nitrogen-containing object to chemically react with the fluorine-containing substance.

22. A non-transitory computer-readable recording medium storing a program that causes, by a computer, a processing apparatus to perform:
(a) providing a state where a product substrate and a nitrogen-containing object are disposed in a process container; and
(b) etching a surface of the product substrate by using a substance X produced by supplying a fluorine-containing substance into the process container in which the product substrate and the nitrogen-containing object are disposed and causing the nitrogen-containing object to chemically react with the fluorine-containing substance.
